(19) United States
(12) Patent Application Publication
(10) Pub. No.: US 2009/0065046 A1
(43) Pub. Date: Mar. 12, 2009

(54) Solar photovoltaic module to solar collector hybrid retrofit

(76) Inventor: Roger DeNault, Santa Cruz, CA (US)

Correspondence Address: Walt Froloff, 273D Searidge Rd, Aptos, CA, 95003, US

(21) Appl. No.: 11/900,557

(22) Filed: Sep. 12, 2007

(51) Int. Cl. H01L 31/042

(52) U.S. Cl. 136/248

(57) ABSTRACT

The present invention discloses a system for a retrofitting a photovoltaic energy collector, by coupling a thermal energy absorbing working fluid casing for flowing heat out to a heat sink The solar module is cooled by the working fluid transferring unproductive heat away from the photovoltaic array and into an exterior heat sink via the cooling fluid circuit, thus making the photovoltaic array more efficient, while adding another energy source. The retrofitting can be done at the consumers convenience, discretion and site, overcoming the current requirement forcing the consumer to decide on one solar technology over another with competing needs.

### BACKGROUND

1. Field of the Invention

The present invention generally relates to solar photovoltaic panels and more specifically, to retrofitting existing solar photovoltaic panels with thermal collectors using working fluid and thermodynamic work cycle, removing photovoltaic panel heat as well as providing beneficial energy streams for thermal heating applications.

The photovoltaic solar panels are the solar design of choice, over other methods of capturing solar energy, mostly for reasons of cost, installation and maintenance. The solar energy market is undergoing exponential growth. There are many different types of photovoltaic solar panels using various materials, generally divided into crystalline and amorphous crystal, CIGS, plastic cells, multifunction concentrators and others. The efficiency of photovoltaic (PV) panels is increasing. The more commercially viable technologies are currently between 15% and 27% of absorbed radiation resulting in direct electric power conversion. The remaining solar energy, 85% to 73%, is lost to waste heat energy. Furthermore, the waste heat in most photovoltaic designs decreases the photovoltaic efficiency by 10% to 20%, since increased cell temperatures generally result in a decrease in cell efficiency. This is all generally considered in the purchase of the photovoltaic panel.

There is a dichotomy in the market, residential verses industrial applications. Also, solar thermal collectors verses solar photovoltaic cells, electrical energy and thermal energy. Thermal solar collectors have had limited success mostly because of the added cost of the thermal portion and more urgent demand for electrical power, and ability to heat air and water from electrical energy sources. Furthermore, the space on a building or structure roof top is at a premium, often not allowing for both electric and thermal solar collection. What is needed are ways to allow for both methods of solar collection without giving up one or the other because of a prior decision.

There have been some combined electrical and thermal solar collectors proposed. Some use flow tubes below plates, with thin perpendicularly heat-conductive web of rigidly connecting plate to flow tubes, inlet and outlet headers at opposite ends of flow tube, making parallel flow tubes below plates, to keep temperature gradients sufficiently low. These all have costs; flow tubes, flow tube construction, manufacturing and building collector, pumping fluid, and insufficient temperature removal. Those have all been proposed to be built at initial manufacturing and time, not separately and independently installable at a later time, as an add on or retrofit.

Still other designs use a substantially unsealed enclosure, an array of photovoltaic cells for converting solar energy to electrical energy located within the enclosure, and a plurality of interconnected heat collecting tubes located within the enclosure and disposed on the same plane as the array of photovoltaic cells for converting solar energy to thermal energy in a fluid disposed within the heat collecting tubes. These again, are costlier tube constructs with interconnected heat collecting tubes located within the enclosure and disposed on the same plane as the array of photovoltaic cell. Instead use open channels, slab geometry conduit and freon or other refrigerant gas working fluid. Open channel surface flow or slab geometry conduits with working fluid liquid or gas or both in the enclosure, or convective and conductive or capillary action energy transfer means may prove less expensive.

Single thin-film solar panel technology is emerging, composed of flexible aluminum substrate, electrically conductive back metal contact layer which could be deposited on the anodized flexible aluminum substrate. An anodized surface electrically insulates the aluminum substrate from the electrically conductive back metal contact layer; a semiconductor absorber layer is deposited on the back metal contact. The semiconductor absorber layer is constructed from a film selected from the group of metals composed of Copper, Indium, Gallium and Selenium, thus its name, CIGS thin film. These are emerging but not yet competitive with the conventional photovoltaic solar panels offered. The CIGS suffer from the deficiency that as they heat up thermally, they become less efficient and therefore less cost effective. Thus CIGS photovoltaic panels suffer from high cost and lower efficiency at higher temperatures.

Generally, photovoltaic solar panels need a way of cooling the cell array in a cost effective manner and solar collectors need to be manufactured and made cheaper. Methods and designs for heat transfer and cooling photovoltaic without expensive insulation, manufacturing costs and smarter heat transfer designs, can harness thermal energy from the photovoltaics and collect the heat where it is needed. If such designs can be incorporated into photovoltaic panel structures, they can produce higher efficiency PV panels and provide hot fluid as a secondary resource. Moreover, existing designs do not allow that the consumer to make a choice of which solar technology to use, and then augment that choice using enhancing technologies. Thus, there is a need for users of photovoltaic panels who also need thermal heating, or solar thermal collectors that require enhancement to photovoltaic collection.

The current solar panel technologies require that the consumer choose one. There is the PV vs. Thermal Collectors, Crystalline vs. Thin-film Amorphous Panels, Thin-film amorphous crystal vs. CIGS, multifunction vs 3D thinfilm. All of the PV varieties come in a type of flat or slightly curved panel array. As the solar panels get hot they become less efficient. The efficiency drop is dependent on the technology; CIGS handle heat better than the Crystalline cells and so forth. Once the technology is chosen, the main problems concerning the use of solar PV panels are high initial costs and the inconvenience of reduced efficiency. However, solar PV combined with solar thermal panel all have advantages, and the consumer is not pressed to chose only one technology that has the highest utility by itself, but not the highest utility over all.

Photovoltaic solar panels require mounting brackets when placed in solar arrays. Some installation effort includes producing an inexpensive mounting system to reduce initial costs of a photovoltaic solar array to reduce the final total cost of installed photovoltaic modules. Current installation and mounting system costs per panel add another 10% to the overall cost. Moreover, thermal heating solar panels generally precludes using photovoltaic solar technologies competing for the same real estate space. These constraints drive the solar module design toward PV panel or thermal collector. What is needed are solar technologies which are more flexible.

What is needed are methods of capturing more total solar energy using the existing panels, better utilizing the initial cost of installing a solar panel array and mounting systems. What is needed are methods for mounting and installing hybridized solar systems on residential, commercial and industrial roofs with existing solar PV panels. A simple and quick hybridization installation could allow economic conversion of individual solar panels into a freestanding system that eliminates the need to penetrate roof seals, or do other costly installation additions. What are needed are retrofitting technologies such that consumers can make open choices about solar technology, upgrade options for higher efficiency and higher utility from the existing solar investment.

Many photovoltaic panels are specifically designed to meet the mission critical needs of telecommunications companies, in such areas of application like telecom systems, including microwave, wireless local loop, cellular, network. Solar PV panels are successfully applied as integrated parts of flashers, warning signs, callboxes, message boards and other critical traffic and railroad safety mechanisms. That is why they are chosen first. However, thermal uses such as water heating can also be used along with these, and enhancing or retrofitting a PV panel to do just that adds utility at some incremental cost. The economics of a converter are critical to a market success. Building a thermal collector panel where 12 to 27 percent of the energy is taken off the top by pv, reduces the possible utility of the thermal collector. However, if the thermal collector can cool the PV panel to increase efficiency of the pv panel, then its utility is increased. There are energy and cost breakevens to account for. What is needed are economic means and methods of retrofitting pv panels either simultaneously to initial installation or at a later date, in compliance with consumer affordability, to include thermal collector technology for capturing heat and turning that into a useable energy stream, such that the combined thermal and PV solar panel serves a higher utility.

As mentioned above, there are many photovoltaic panels in the marketplace, with different material, size and shaped panels. These many designs all lend themselves to increase efficiency increases by cooling the panel. Retrofitting technology would need to be innovative in adaptability and adjustability to conform with a diverse market of existing pv panels. Thus, what is needed are economical ways of retrofitting photovoltaic solar panels such that they are cooled to increase efficiency and capture the heat into working fluids or to heat water. They must handle diverse panel sizes and designs. The installation and mounting costs are incurred in the retrofit as well, but installed later and only on photovoltaic panel sites which can make use of the thermal heat energy. Thus finds not available in the past may become available for an incremental improvement in energy capture.

### SUMMARY

The present invention discloses a system for retrofitting a photovoltaic solar panel to become a photovoltaic thermal collector hybrid. Aspects of the invention make the retrofit adjustable to most existing industrial photovoltaic solar modules designs and sizes. An integrated heat exchanger unit is coupled to the solar module during installation of retrofit. A heat exchanger is used for extracting heat from the PV solar module, transferring heat to a working fluid connected to an exterior heat sink. Thus solar radiation not converted in the photovoltaic module to electricity and remaining in the form of heat is removed by the working fluid transferring heat away from the photovoltaic collector and into an exterior heat sink. Various flow through exchanger materials and designs are shown.

### BRIEF DESCRIPTION OF DRAWINGS

Specific embodiments of the invention will be described in detail with reference to the following figures.

FIG. 1 is an exploded assembly drawing of a retrofitted solar module according to an embodiment of the invention.

FIG. 2a shows a bottom view of an assembled retrofitted solar module in accordance with an embodiment of the invention.

FIG. 2b shows a side view of an assembled retrofitted solar module in accordance with an embodiment of the invention.

FIG. 3a shows a side view of an integrated heat exchanger unit in accordance with an embodiment of the invention.

FIG. 3b shows a cross-section view of an integrated heat exchanger unit in accordance with an embodiment of the invention.

FIG. 3c shows a detail view of an integrated heat exchanger unit fluid conduit integration in accordance with an embodiment of the invention.

FIG. 4 illustrates heat exchanger unit solar module coupling straps in accordance with an embodiment of the invention.

FIG. 5a illustrates an exploded assembly of an embodiment of the invention.

FIG. 5b illustrates an exploded assembly of a heat exchanger module to solar module coupling in accordance with an embodiment of the invention.

FIG. 6a illustrates a completed assembly of an embodiment of the invention with attachment coupling bar.

FIG. 6b shows an attachment bar details in accordance with an embodiment of the invention.

FIG. 7a shows a side view of an integrated heat exchanger unit in accordance with an embodiment of the invention.

FIG. 7b shows a cross-section view of an integrated heat exchanger unit in accordance with an embodiment of the invention.

FIG. 7c shows a detail view of an integrated heat exchanger unit fluid conduit integration in accordance with an embodiment of the invention.

### DETAILED DESCRIPTION

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

Objects and Advantages

The present invention is a system and method using existing solar energy capacity to increase energy extraction through retrofit. Accordingly, it is an object of the present invention to provide synergistic and cost effective solar technology, technology that combines existing on site photovoltaic technology with retrofittable, installable and affordable thermal solar collector technology.

It is another object of the present invention to provide embodiments designed using the known and standard size solar modules in the photovoltaic module market place, harness solar panel heat otherwise throw away as waste, increase solar photovoltaic efficiency by providing a cooling to the photovoltaics. The increased solar module utility allows consumers both solar photovoltaic and collector technologies in one converted unit, even if the consumer chose the photovoltaic technology first.

Another object is to provide technology that is not only energy economic, but practical from an installation standpoint. Retrofit technology must build on existing devices and structures, which open a number of challenges related to compatibility, adjustability, scalability, and affordability.

### EMBODIMENTS OF THE INVENTION

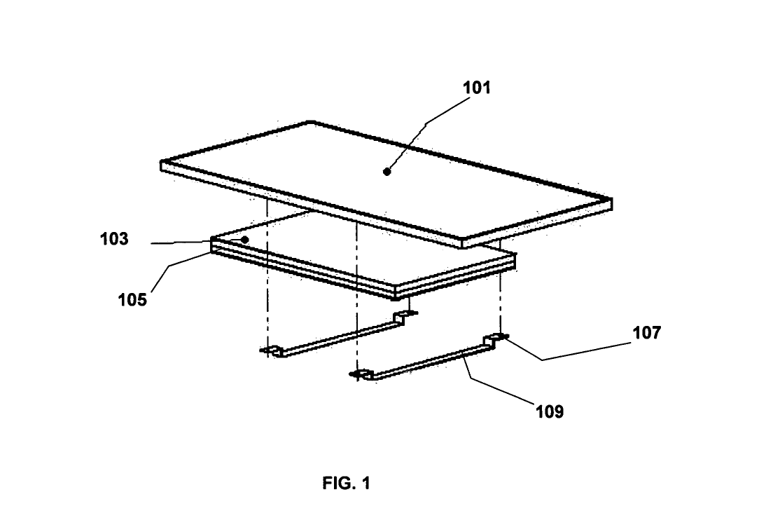

FIG. 1 is an exploded assembly drawing of a retrofitted solar module according to an embodiment of the invention. The existing solar module 101 to be retrofitted is coupled to an integrated heat exchanger 103 which consists of a thin flat heat exchanger 103 rigidly coupled to an insulating back layer 105 to help collect the solar module 101 heat in the heat exchanger 103 working fluid. The integrated heat exchanger 103 can be rigidly coupled to the solar module 101 in various fashions such as with heat conducting conformable surface sealer, fasteners, adhesive materials, etc. In addition or in lieu of, rigid straps 109 with integrated heat exchanger 103 conforming bends 107 with fastener attachment to the solar panels can be an effective coupler. The straps 107 can be attached to existing holes in the solar module 101 frame, which carry certain standard size threaded holes which can be used for this purpose.

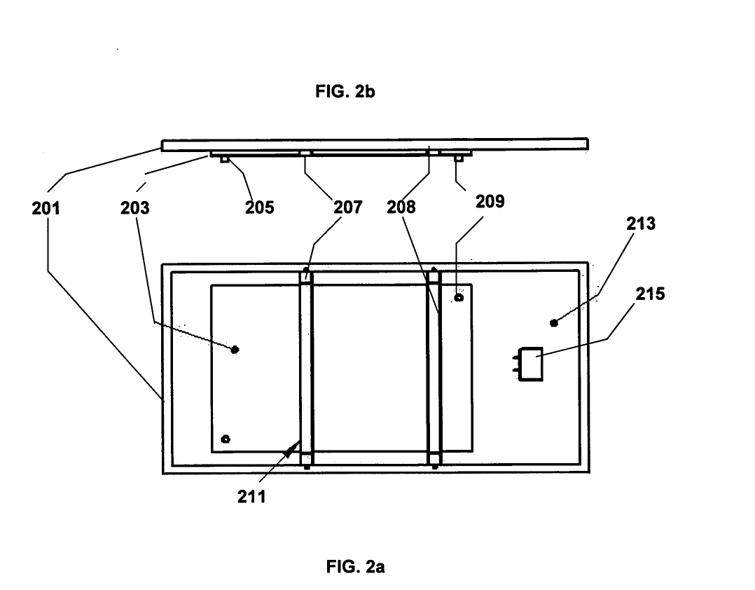

FIG. 2b shows a side view of the FIG. 2a bottom view of an assembled retrofitted solar module respectively, in accordance with an embodiment of the invention. The PV panel frame 201 of the existing solar module provides the physical support necessary for the retrofit integrated thermal unit. The retrofit comprises an integrated heat exchanger unit 203 which is firmly attached to the solar module 213 panel frame 201. The integrated heat exchanger 203 has a cooling water inlet 205 and cooling water outlet 209 ports, for coupling a heat sink such as a water heater or swimming pool. Securing strap 207 208, help firmly couple the integrated heat exchanger 203 with large heat transfer area facing the solar module 213. The entire solar module 213 may not be covered by the integrated heat exchanger 203 area, but a large part of the area will be covered. This makes the retrofit unit adjustable to most standard size pv panels, as their dimensions are known and may be accommodated by a number of set retrofit exchanger sizes. The power junction box 215 on many pv modules may pose and addition interference if the total pv module area is targeted for cover. Hence a judicial choice of solar module 213 coverage area will go a long way to production of standard size integrated heat exchanger 203 units. The securing strap 211 will also find the standard size integrated heat exchanger 203 easier to define its dimensions, further reducing installation costs and production costs.

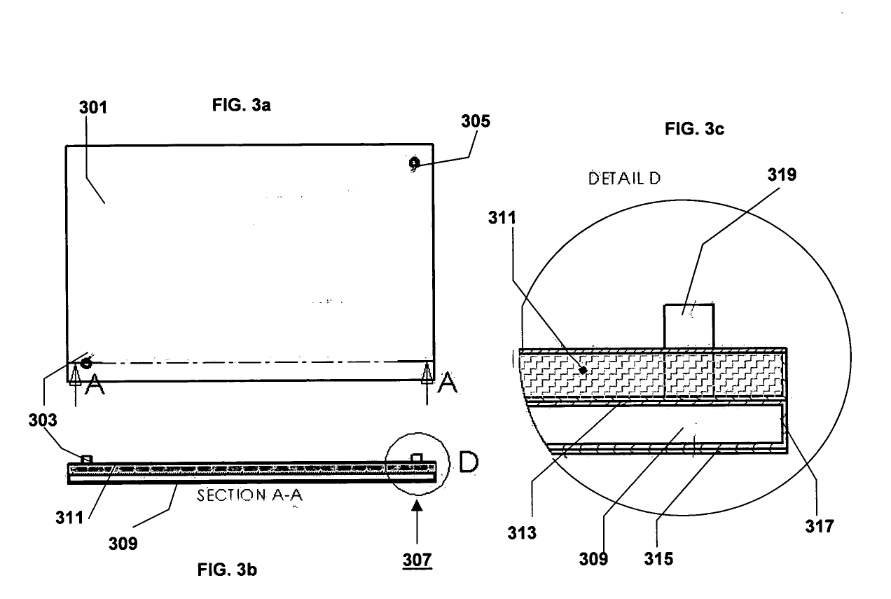

FIG. 3a, 3b and 3c show a top view, side view and detail view respectively, of an integrated heat exchanger unit in accordance with an embodiment of the invention. The integrated heat exchanger unit 301 is a solar module flat surface conforming attachment. Installation to existing solar modules is primary. Therefore the integration of the layers in the heat exchanger 301 unit work towards that objective. The integrated heat exchanger unit 301 outward facing side is shown with the cooling water inlet 305 connection and the cooling water outlet 303 connectors protruding outward. These can also be conducted in various directions to minimize pressure drops or flow resistance, the inlet 305 and outlet 303 ports can be reversed with the cooling water inlet being bottom driven. Many other cooling fluids can be used including gas working fluids. The side view, FIG. 3b, shows a layered design of the integrated exchanger 301 unit, with the insulation layer 311 outward from the heat exchanger layer 309, where the insulating layer 311 acts as an adiabatic side to the exchanger layer 309. The exchanger layer 309 is sandwiched between the insulation layer 311 and conformably adjacent to the existing solar module for maximum heat flow to cool the solar module on its other side. The edges of the integrated unit 301 can also be insulated, edge insulation not shown. In some embodiments, the edges will have thermal conducting flexible material, to maintain fluidic integrity despite module surface warp or deformation.

The detail D 307 FIG. 3c illustrates the details in the layered integrated heat exchanger unit. The unit 301 has a slab shape with one side facing away from the solar module and comprising the insulation 311 layer. The material for the insulation could be typical insulating material available off the shelf, uniformly distributed as shown in the cross-section view. The slab or plane maybe curved for some PV designs with the heat exchanger unit conformably curved to maintain maximum heat flow. The coolant inlet 319 orifice penetrates through the insulation 311 and is operatively connected to the heat transfer 309 layer. The separator 313 between the insulation 311 and the heat exchanger 313 is of rigid or flexible material, which need not be a good thermal conductor, but serves in this embodiment as part of the exchanger layer 309 housing or containment. The heat exchanger layer 309 is contained in a good thermal conductor housing 315, except for the edge 317 housing which may be of thermal insulating material, to minimize thermal losses and maximize heat transferred to working fluid inside the exchanger layer 309. The heat exchanger 301 unit is self contained, and of thin slab surface aspect dimensions to minimize costs of manufacturing and installation, while maximizing overlay of thermal area available on the solar module host.

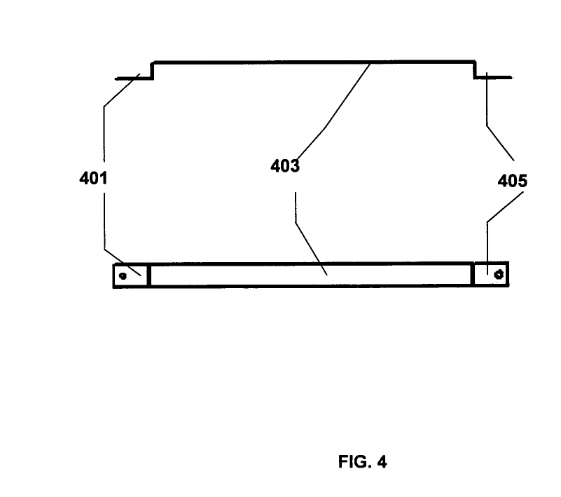

FIG. 4 illustrates heat exchanger unit solar module coupling straps in accordance with an embodiment of the invention. The coupling straps 403 can be made of rigid or flexible material, but the strap 403 must sustain the partial weight of the integrated exchanger snuggly against the solar module. The strap 403 can have discrete right angle bends 401 405 through which pre-made threaded or straight holes can be used to screw or fasten, to firmly attach the straps around the integrated exchanger unit and couple them to pre-made attachment holes on the solar module panel. Leaf springs and thermal conducting bonding material are also elements for coupling the exchanger unit to the existing solar module panel. The straps 403 are extensibly adjustable, for a more diverse solar module size market, or they may be fixed for simplicity in installation and economy of cost.

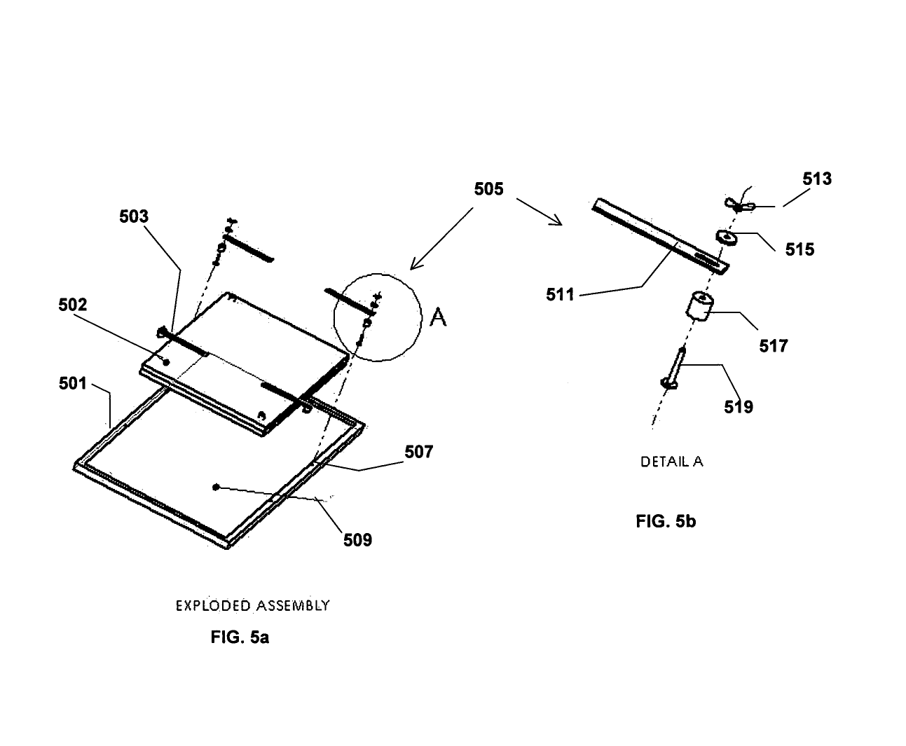

FIG. 5a illustrates an exploded assembly view of an embodiment of the invention. The solar PV module 509 back side is integrated in a module frame 501 sometimes having pre-drilled or straight holes 507 in the frame 501. The heat exchanger unit 502 is coupled firmly to the solar PV module 509 back side through the use of attachment or constraint bars 503 and fasteners, which are designed for quick easy installations. The FIG. 5a shows detail assembly A 505 which is shown expanded in FIG. 5b

FIG. 5b illustrates an exploded assembly of a heat exchanger unit coupling to solar PV module on an embodiment of the invention. Here the bolt 519 is inserted from the opposite side of the solar module frame 501, locking the frame 501 between the bolt 519 head through the hole and the remainder of the assembly. This included the standoff bushing 517 followed by the coupling or attachment bar 511, followed by a washer 515 and followed with a wing nut 513 fastener tightened to a pre-determined torque. This type of coupling of the hybrid exchanger unit to a pre-existing solar PV module provides a universal fit and installation process, designed to conform with most existing solar photovoltaic modules.

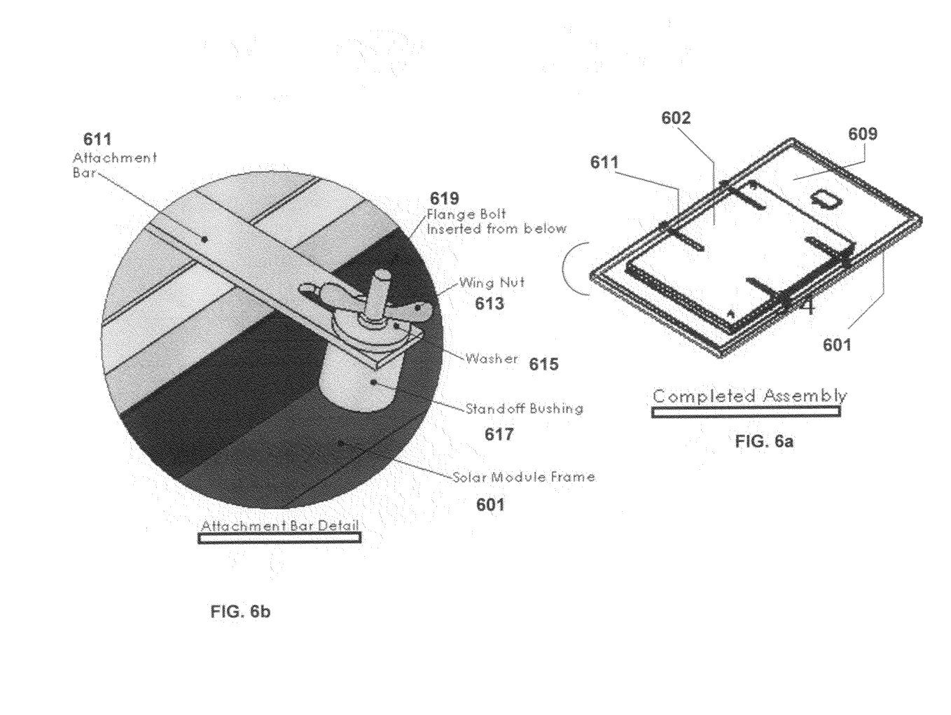

FIG. 6a illustrates a completed assembly of an embodiment of the invention with attachment coupling bars 611. The frame 601 surrounds the solar module 609 whose back side is adjacent to the heat exchanger unit 602. Exchanger unit 602 is adjacent to the solar module 609 back side and is coupled with the four attachment bars 611. The coupling complete assembly details are shown in FIG. 6b. A flanged bolt 619 is shown positioned through the module frame 601, a standoff bushing or spacer 617, through one side of the attachment bar 611 with the distal end of the attachment bar 611 extended towards the opposite side of the frame 601. The bolt 619 is held secure by the addition of a washer 615 and nut 613, a wing nut is shown for easy manual installation.

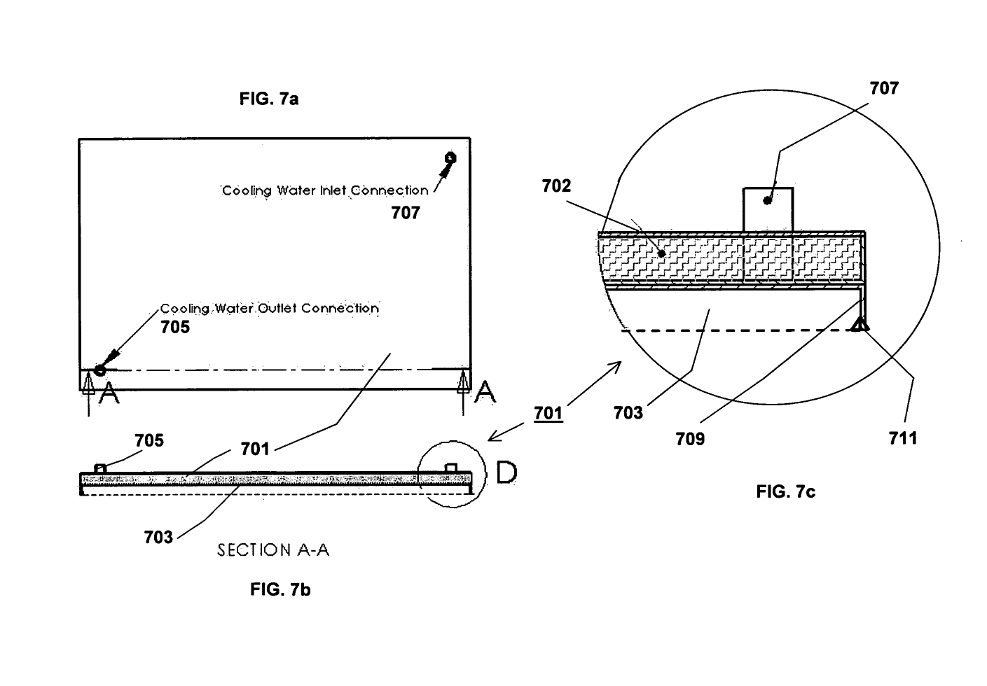

FIG. 7a shows a back side view of an integrated heat exchanger unit in accordance with another embodiment of the invention. Viewing from the back of the exchanger unit 701, the coolant is introduced at the upper right inlet 707 and exits from the lower left outlet 705. The cross section A-A is shown in FIG. 7b reveals that the exchanger unit 701 solar module side appears without containment of the working fluid on one side. The solar module back side surface will be coupled to this side of the exchanger, serving as a fluid boundary without the additional heat flow resistance. Working fluid is contained within the exchanger unit and the solar panel with fluidic seals on the exchanger contact edges. These are shown in the Detail D 701 of FIG. 7c.

FIG. 7c shows a detail view of an integrated heat exchanger unit fluid conduit integrated in accordance with an embodiment of the invention. The working fluid exchanger inlet 707 transports fluid through the exchanger 701 insulation 702 and into the heat exchanger 703 fluid heat extraction volume, where the fluid takes heat from the solar module back side through conduction in the module back side and convection to the adjacent flowing fluid, which then removes heat out with the convecting fluid. In another embodiment of the invention, the exchanger edge 709 fits conformably against the solar PV module back side holding a fluidic tight seal 711 which is flexible enough to provide a leak proof seal yet durable enough for the solar module heating surface.

A further embodiment will include spacers, not shown, between the exchanger layer volume 703 inside surface and the solar module backside adjacent surface, maintaining the fluid extraction volume 703 from exchanger surface warps while providing working fluid channels for a pre-designed flow pattern.

Many types of heat exchanger designs are possible, such as flow tubes, thin perpendicularly heat-conductive web of rigidly connecting volume to flattened flow tube channels, inlet and outlet headers at same side or opposite ends of flow tube, parallel flow tubes below plates, counter current flow through, etc. The tubes may become flattened rectangular channels to reduce the effective heat conduction distance from the working fluid to the heat source in a flat rectangular geometry. The working fluid need not be water, but can be any working fluid and even gas. Working fluids to increase thermal cycle efficiency such as a gas with phase change to enhance the removal of heat and reduce pumping energy, are also envisioned in some embodiments. The open side exchanger edge seals may be from any material fitting the exchanger edges conformably against the solar module back side, and durably for the heat and pressure conditions they will be subjected to over a finite life.

Therefore, while the invention has been described with respect to a limited number of embodiments, those skilled in the art, having benefit of this invention, will appreciate that other embodiments can be devised which do not depart from the scope of the invention as disclosed herein. Other aspects of the invention will be apparent from the following description and the appended claims.

What is claimed is:

1. A photovoltaic solar energy module to a photovoltaic thermal collector hybrid retrofit comprising:
a pre-existing photovoltaic solar module,
an integrated heat exchanger unit coupled to the solar module, exchanger for extracting heat from the module and transferring heat to a working fluid connected to an exterior heat sink, and
the integrated heat exchanger unit retrofitting the solar module
whereby solar radiation not converted to electrical energy in the pre-existing photovoltaic module is removed as heat energy by the retrofit working fluid and thereby cooling the solar module and making its operation more efficient.

2. A system as in claim 1 further comprising an integrated heat exchanger using a flow grid of flattened tubular channels connected by headers with gravity or forced convection flow.

3. A system as in claim 1 further comprising an integrated heat exchanger with flow through a flattened serpentine channel under gravity or forced convection.

4. A system as in claim 1 further comprising convecting working fluid flowing through an external secondary exchanger as heat sink.

5. A system as in claim 1 further comprising an integrated heat exchanger extracting heat energy by flowing working fluid through a volume enclosed by the exchanger unit abutted to the solar module backside and with fluid tight sealed edge exchanger coupling.

6. A system as in claim 5 further comprising spacer structures between the exchanger and module surfaces which also act as channels for the working fluid.

7. A system as in claim 1 further comprising a thermal conducting adhesive or bonding material for coupling the integrated heat exchange to the solar panel.

8. A system as in claim 1 further comprising coupling the solar panel with the heat exchanger through adjustable or extensible rigid straps, attachment bars or leaf springs assemblies.

9. A system as in claim 1 further comprising flattened thin tube exchanger reducing average length of conduction from the module to working fluid.

10. A system as in claim 1 further comprising a heat exchanger module with conformable edge material creating a fluid tight seal for direct contact between exchanger coolant fluid and solar module back side.

11. A system as in claim 1 further comprising an increased extraction of solar energy with the same pre-existing solar module photovoltaic dimensions.

12. A system as in claim 1 further comprising installation of the exchanger unit independently of the installation of the photovoltaic solar module.
